(19) United States
(12) Patent Application Publication
(10) Pub. No.: US 2006/0225271 A1
(43) Pub. Date: Oct. 12, 2006

(54) System and method for insertion and retention of a daughter card in a motherboard

(76) Inventors: Richard M. Barina, Wellington, FL (US); Dean F. Herring, Youngsville, NC (US); Paul A. Wormsbecher, Apex, NC (US)

Correspondence Address: SAWYER LAW GROUP LLP, PO BOX 51418, PALO ALTO, CA, 94303, US

(21) Appl. No.: 11/102,184

(22) Filed: Apr. 7, 2005

(51) Int. Cl. H05K 3/36; B23P 19/00

(52) U.S. Cl. 29/830; 29/832; 29/764; 29/758

(57) ABSTRACT

System and method aspects for insertion and retention of a daughter card in a motherboard include a latching device mounted on a daughter card, and a motherboard including a pair of posts, the pair of posts supporting reception of the latching device, wherein no standard industry backetry is needed to hold the daughter card on the motherboard. The latching device further includes a handle with connection arms mounted on a top edge of the daughter card, where the connection arms adjust position to allow insertion and removal of the daughter card. In one embodiment, the connection arms comprise spring action arms, and in another embodiment, the connection arms comprise lever action arms.

### FIELD OF THE INVENTION

The present invention relates to daughter card insertion and retention in a computer system motherboard, and more particularly to daughter card insertion and retention without use of standard industry backetry.

### BACKGROUND OF THE INVENTION

In computer processing systems, the inclusion and addition of varying system enhancements is sometimes done with the use of daughter cards that are plugged into the motherboard of the computer. Usually, standard industry backetry, such as backetry that complies with the peripheral component interconnect (PCI) specifications, is available to retain the daughter card on the motherboard. However, at times, such standard backetry is not available. For example, standard industry backetry may not be in place due to the daughter card being plugged into the motherboard in an off specification location for various system requirements.

Accordingly, a need exists for a card retention and insertion approach without use of standard industry backetry. The present invention addresses such a need.

### BRIEF SUMMARY OF THE INVENTION

System and method aspects for insertion and retention of a daughter card in a motherboard are described. The aspects include a latching device mounted on a daughter card, and a motherboard including a pair of posts, the pair of posts supporting reception of the latching device, wherein no standard industry backetry is needed to hold the daughter card on the motherboard. The latching device further includes a handle with connection arms mounted on a top edge of the daughter card, where the connection arms adjust position to allow insertion and removal of the daughter card. In one embodiment, the connection arms comprise spring action arms, and in another embodiment, the connection arms comprise lever action arms.

With the present invention, a straightforward and effective manner of providing insertion and retention of a daughter card in a motherboard is achieved. The invention is activated automatically through a single human interaction point as the card is being plugged and unplugged from the motherboard. The invention solves the problems of lost card guiding and card retention in a stand alone location. Additionally, the invention is designed for human factors intervention which is tool-less handling and single point pull-push activation. These and other advantages of the aspects of the present invention will be more fully understood in conjunction with the following detailed description and accompanying drawings.

### BRIEF DESCRIPTION OF SEVERAL VIEWS OF THE DRAWINGS

FIGS. 1 and 2 illustrate a first embodiment of a card insertion and retention system in accordance with the present invention.

FIGS. 3, 4, 5, 6, and 7 illustrate a second embodiment of a card insertion and retention system in accordance with the present invention.

### DETAILED DESCRIPTION OF THE INVENTION

The present invention relates to daughter card insertion and retention in a motherboard without use of standard industry backetry. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

In accordance with the present invention a card insertion and retention system is provided that utilizes a latching device mounted on top of a card in conjunction with post mounted on a motherboard. As described further hereinbelow, the latching device includes a handle with connection arms that adjust position for the insertion and removal of a daughter card. A first embodiment utilizes spring action arms and a second embodiment utilizes lever action arms.

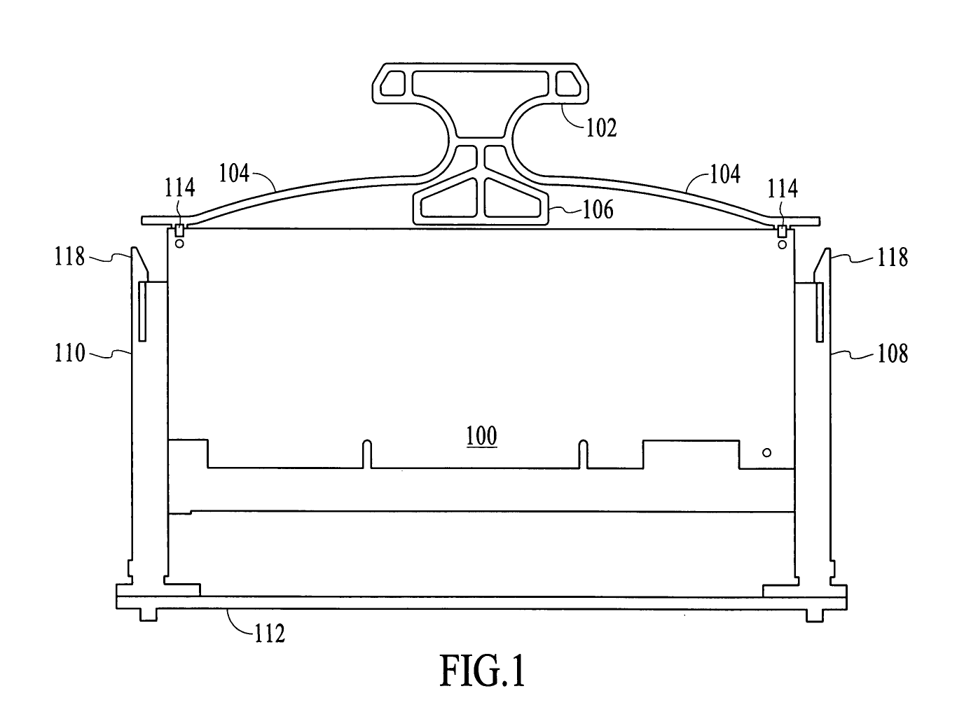

Referring to FIG. 1, a daughter card 100 is shown in accordance with the first embodiment of the latching device mounted on a top edge of the daughter card 100 that includes a handle 102 and spring action arms 104. The spring action arms 104 are attached to the handle 102 via an expanding spring member 106. The expanding spring member 106 is situated between the handle 102 and the spring action arms 104. The handle 102, spring action arms 104, and expanding spring member 106 are all part of one piece preferably made out of a plastic sufficient to balance the rigidity and spring attributes of the design. Two posts 108, 110 (e.g., made of plastic or spring steel) mounted on a motherboard 112 are also shown and receive side edges of the daughter card 100.

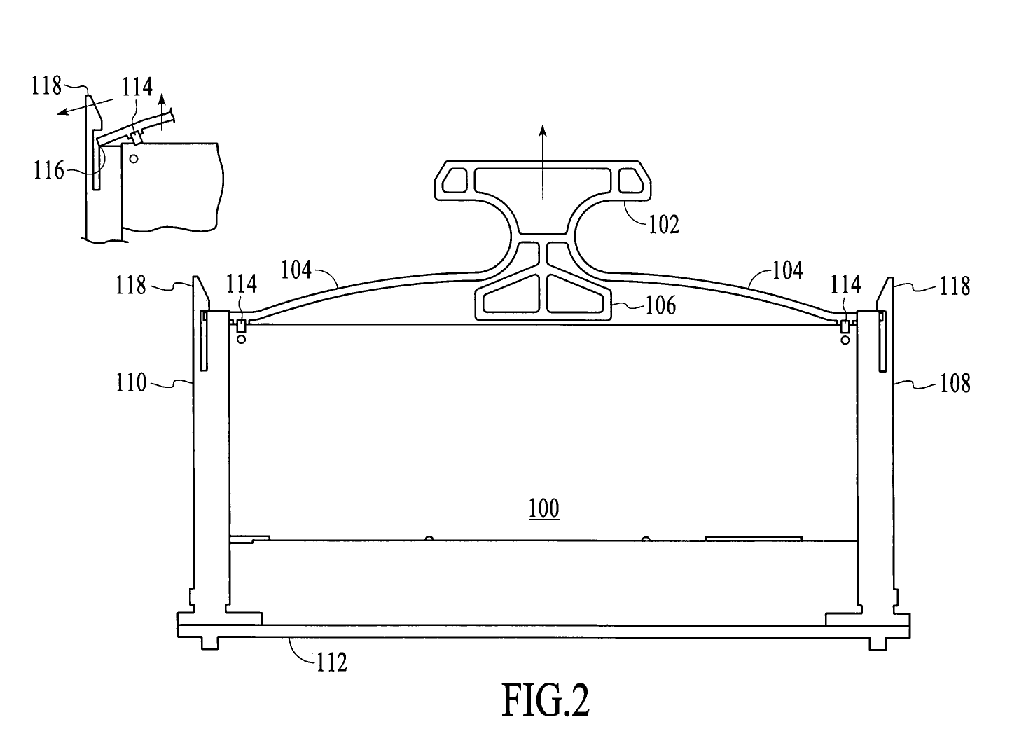

Prior to inserting the daughter card 100 into the posts 108, 110, the latching device lays flat against the top of the card 100 and is essentially a static body. As the card 100 is put into the posts 108, 110, the ends of the spring action arms 104 come into contact with snap portions of the posts 108, 110 substantially simultaneously. The snap portions move out of the way to receive the end portions of the spring action arms 104. The latching device is attached at lever locations 114 via a roll pin or other suitable fastening device which goes through a hole in the daughter card 100 at the lever locations 114 and allows for the spring action arms 104 to rotate. Spring action arms 104 are flattened when the daughter card 100 is pushed into the motherboard. Member 106 is a limiter and card pusher. When pushing down on handle 102, spring arms 104 flatten and touch limiter 106, and the limiter 106 impinges on the card 100 top and pushes it in. FIG. 2 illustrates the final position of the daughter card 100 fully inserted into the motherboard 112.

To remove the daughter card 100 from the motherboard 112, the handle 102 is grasped and pulled upward. This action transfers the upward movement of the handle 102 to the expanding spring member 106 and ultimately to the spring action arms 104. As the handle 102 is being pulled up, the spring action arms 104 bow up and the ends of the spring action arms 104 rotate downward. As the arms 104 rotate, the ends hit a shelf 116 on the posts 108, 110, (as shown in the close-up portion of FIG. 2) which helps cam the daughter card 100 out. The spring action arms 104 are tilted at an angle and have somewhat helped cam/lever the daughter card 100 out. The angle of the spring action arms 104 also allows them to slip past the snaps 118 of the posts 108, 110 that spring out of the way. If the spring action arms 104 do not attain this angle, they will not slip out from under the snaps 118 of the posts 108, 110. By tuning the expanding spring member 106 to a force required to hold the spring action arms 104 down in position and by the spring stiff nature of the spring action arms 104, the ends can remain locked/retained even if they experience a force caused by the daughter card 100 unseating during shipping.

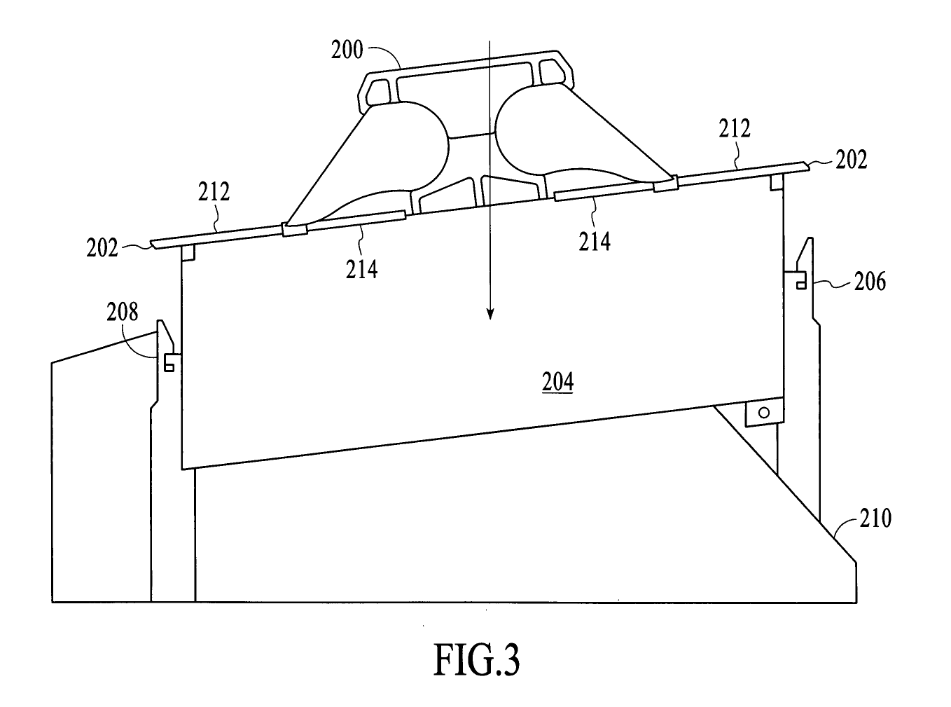

FIG. 3 illustrates a second embodiment of the latching device in accordance with the present invention. The latching device includes a handle 200 and lever action arms 202 mounted on top of a daughter card 204. Two posts 206, 208 mounted on a motherboard 210 receive the edges of the daughter card 204. The lever action arms 202 are mounted on the top outside edges of the daughter card 204 and include a lever end 212 and a slider end 214, where the slider end 214 is the continuation of the lever end 212 under and through a portion of the handle 200, which is hollow.

The handle 200 is shown as a rigid member with two ends extending toward the lever action arms 202 with the hollow end of each handle extension receiving the slider ends 214 of the lever action arms 202. The handle 200 is not attached to the card but is kept in place by the slider extensions of the lever action arms 202 whereby one lever action arm 202 is assembled to the daughter card 204 first, then the handle 200, then the other lever action arm 202. Done in that order the handle 200 is then trapped between the lever action arm 202 sliders. The lever action arms 202 are attached via a roll pin or other suitable fastening device which goes through a hole in the daughter card 204 at the lever pivot location 216. The fastening must allow for the lever action arms 202 to rotate.

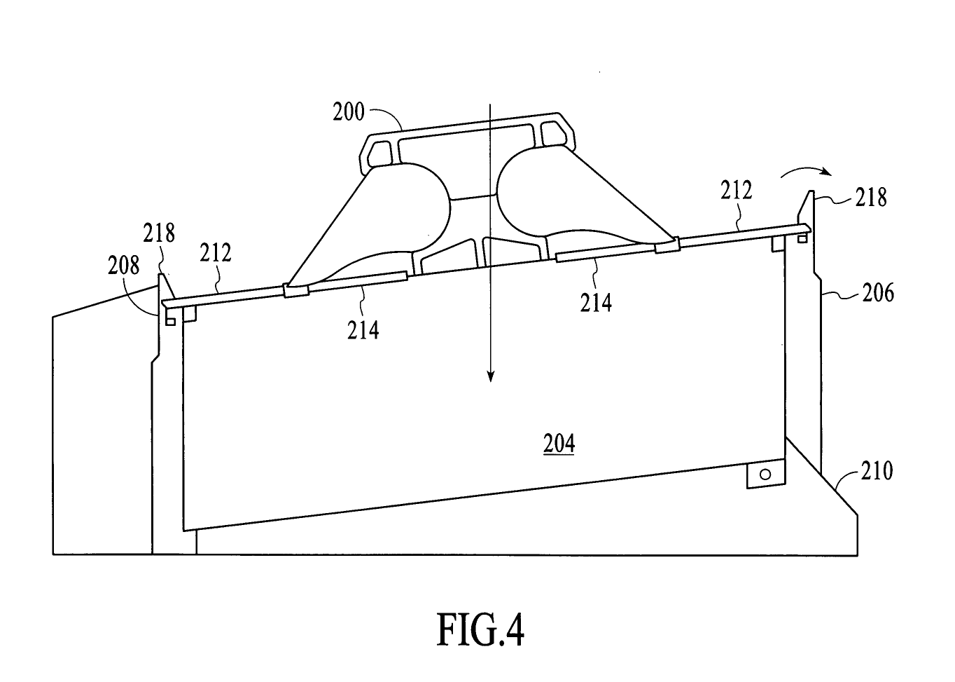

As the card 204 is inserted into the board 210, the lever ends 212 of the lever action arms 202 come into contact with the upright post snap features 218 of the two posts 206, 208 substantially simultaneously. The snap features 218 on the posts 206, 208 move out of the way via a spring cross section of the posts 206, 208, which are made of a material such that the snap features 218 will spring out of the way, e.g., a plastic or spring steel design. Once the card 204 is seated all the way the snap features 218 ‘snap’ back into place and the latching device is retained. FIG. 4 illustrates the latching device mounted to both the daughter card 204 and motherboard 210 with the daughter card 204 seated fully into the motherboard 210. A pin in hole device between the handle 200 and the lever action arms 202 will stop the handle 200 from coming up when the handle 200 is all the way seated. The pin goes from the handle 200 into the sliders preventing them from sliding—thus locking the handle to the sliders and the sliders at the horizontal such that the card will not come out of the posts 206, 208 until the pin is disengaged. This pin in hole device allows for the locking or retention of the lever action arms 202 should the lever ends 212 see a force caused by the daughter card unseating during shipping.

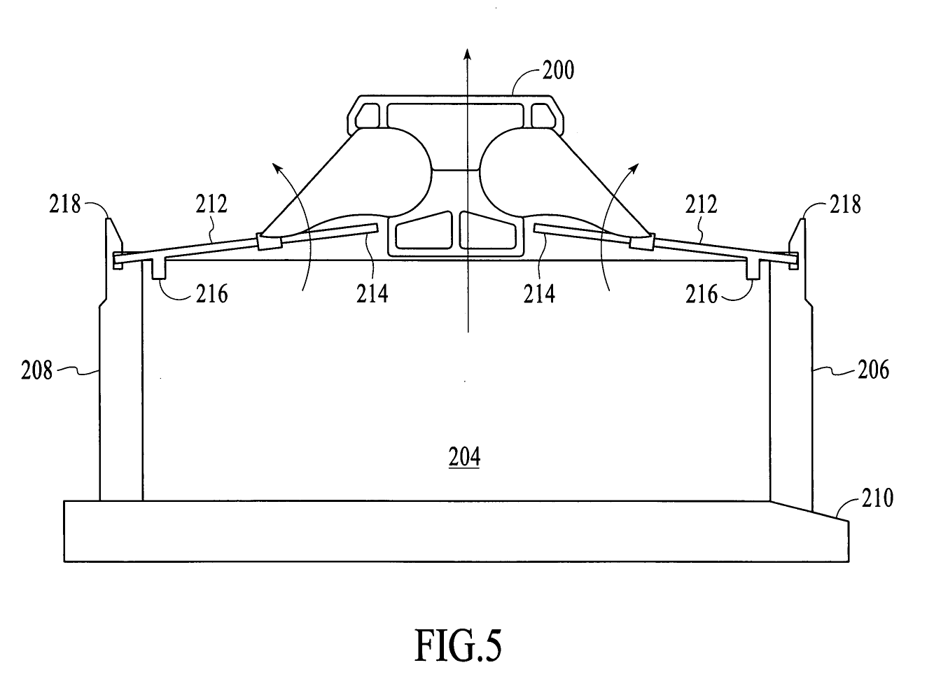

Referring to FIG. 5, the removal or retraction process is started by lifting on the handle 200 with the intention of removing the card 204. The handle 200 lifts up, and at the same time, the lever action arms 202 start to rotate because the lever slider ends 214 are captured within the hollow ends of the handle 200. The lever action arms 202 pivot about the pivot location 216 on the card 204, and the handle hollows allow the rotation to occur while also allowing a sliding of the lever slider ends 214 within the handle hollows. Thus, as the handle 200 is lifted up, the slider ends 214 slide to a set distance whereby they are contained within the hollow and can slide no more (e.g. they bind up and stop the upward distance of the handle and the rotation of the pivot arms). At this point, the angle for disengagement from the snap features of the posts 206, 208 can begin. As the lever action arms 202 rotate, the tips of the lever action arms 202 hit a shelf 220 on the posts 206, 208 and help cam the card 204 out.

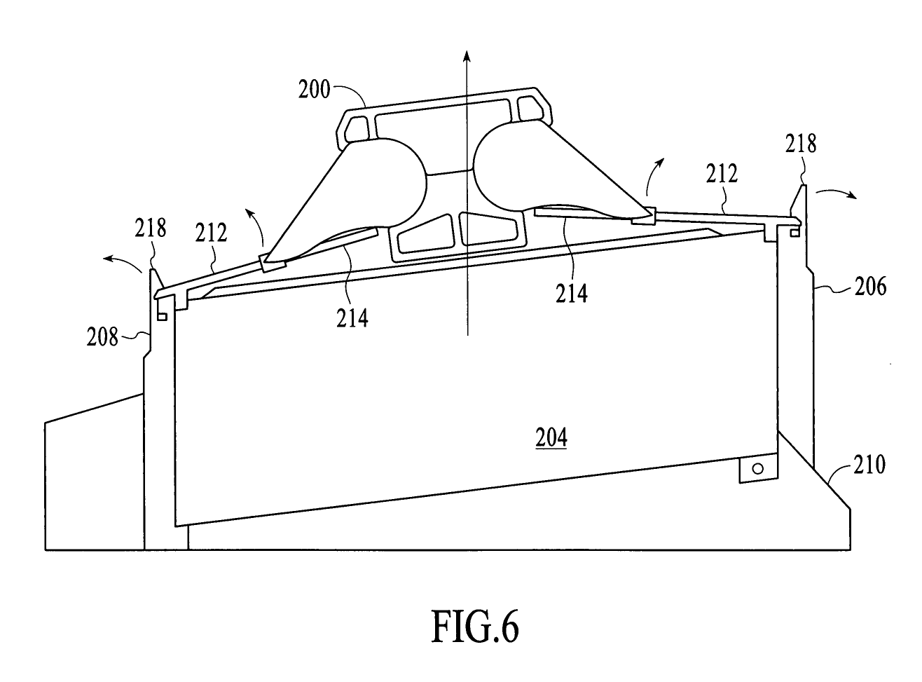

As shown in FIG. 6, the card 204 is starting to pull out of the posts 206, 208 on the motherboard 210. At this time, the handle 200 has stopped all upward movement relative to the top of the card 204 via the slider ends 214 on the lever action arms 202 limiting the handle travel, since the tips of the slider ends 214 are not able to slide further as they bind against the handle bottom. The lever action arms 202 are tilted at an angle and have somewhat helped cam/lever the card 204 out. The angle of the lever action arms 202 also allows them to slip past the snap features 218 of the posts 206, 208, with the snap features 218 bending or springing back out of the way. If the lever action arms 202 do not attain this angle, they will not slip out from under the snap features 218.

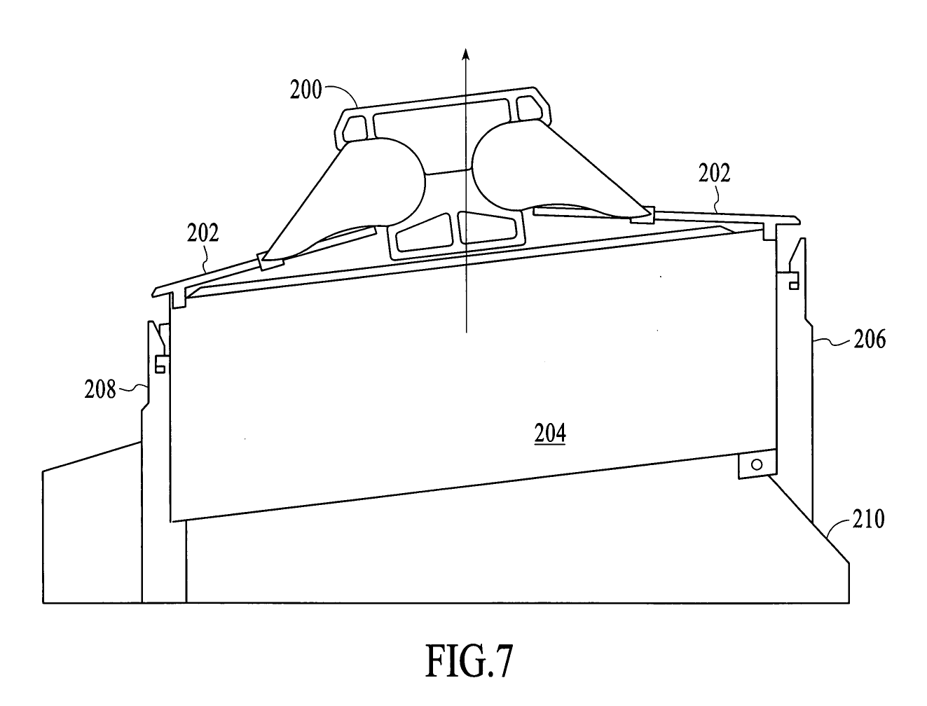

Once free from the posts 206, 208, retraction can be completed. FIG. 7 shows the card 204 and latching device free of the motherboard 210 and free of the posts 206, 208. Insertion can now occur again completing the retraction and insertion cycle.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

We claim:

1. A system for insertion and retention of a daughter card in a motherboard, the system comprising:
a latching device mounted on a daughter card; and
a motherboard including a pair of posts, the pair of posts supporting reception of the latching device, wherein no standard industry backetry is needed to hold the daughter card on the motherboard.

2. The system of claim 1 wherein the latching device further comprises a handle with connection arms mounted on a top edge of the daughter card.

3. The system of claim 2 wherein the connection arms adjust position to allow insertion and removal of the daughter card.

4. The system of claim 3 wherein the connection arms further comprise spring action arms.

5. The system of claim 4 wherein the spring action arms adjust between a relaxed spring arm position and a bowed spring arm position.

6. The system of claim 3 wherein the connection arms further comprise lever action arms.

7. The system of claim 6 wherein the lever action arms adjust between a straight position and a rotated upward position.

8. The system of claim 7 wherein the lever action arms slide from the straight position to the rotated upward position.

9. The system of claim 1 wherein the pair of posts securely receive the daughter card at each side edge of the daughter card.

10. The system of claim 9 wherein the pair of posts further comprise a snap portion for receiving and holding an end of each of the connection arms.

11. A method for insertion and retention of a daughter card in a motherboard, the method comprising:
providing a latching device mounted on a daughter card; and
receiving the latching device via a pair of posts on a motherboard to securely hold the latching device, wherein no standard industry backetry is needed to hold the daughter card on the motherboard.

12. The method of claim 11 wherein providing a latching device further comprises providing the latching device as a handle with connection arms mounted on a top edge of the daughter card.

13. The method of claim 12 wherein the connection arms adjust position to allow insertion and removal of the daughter card.

14. The method of claim 13 wherein the connection arms further comprise spring action arms.

15. The method of claim 14 wherein the spring action arms adjust between a relaxed spring arm position and a bowed spring arm position.

16. The method of claim 13 wherein the connection arms further comprise lever action arms.

17. The method of claim 16 wherein the lever action arms adjust between a straight position and a rotated upward position.

18. The method of claim 17 wherein the lever action arms slide from the straight position to the rotated upward position.

19. The method of claim 10 wherein receiving the latching device further comprises receiving the latching device via the pair of posts at each side edge of the daughter card.

20. The method of claim 19 wherein the pair of posts further comprise a snap portion for receiving and holding an end of each of the connection arms.

21. A system for insertion and retention of a daughter card in a motherboard, the system comprising:
a daughter card;
a motherboard for receiving the daughter card; and
a latching device mounted on a top edge of the daughter card for inserting and removing the daughter card from the motherboard, the latching device comprising a handle with connection arms that adjust position to allow insertion and removal of the daughter card.

22. The system of claim 21 wherein the connection arms further comprise spring action arms that adjust between a relaxed spring arm position and a bowed spring arm position.

23. The system of claim 21 wherein the connection arms further comprise lever action arms that adjust by sliding between a straight position and a rotated upward position.

24. The system of claim 21 wherein the motherboard further comprises a pair of posts that securely receive the daughter card at each side edge of the daughter card.

25. The system of claim 24 wherein the pair posts further comprise a snap portion for receiving and holding an end of each of the connection arms.
